(19) United States
(12) Patent Application Publication
(10) Pub. No.: US 2019/0341275 A1
(43) Pub. Date: Nov. 7, 2019

(54) EDGE RING FOCUSED DEPOSITION DURING A CLEANING PROCESS OF A PROCESSING CHAMBER

(71) Applicant: Lam Research Corporation, Fremont, CA (US)

(72) Inventors: Yansha JIN, Fremont, CA (US); Zhongkui Tan, San Jose, CA (US); Tyler Kent, Sunnyvale, CA (US); Haoquan Yan, Fremont, CA (US); Qian Fu, Pleasanton, CA (US); Anthony Contreras, Stockton, CA (US)

(21) Appl. No.: 15/972,927

(22) Filed: May 7, 2018

(51) Int. Cl. H01L 21/67; H01J 37/32; B08B 7/00; B08B 5/00

(52) U.S. Cl. CPC H01L 21/67028; H01J 37/32862; H01J 2237/335; B08B 7/0035; B08B 5/00; H01J 37/32449

(57) ABSTRACT

A method for performing a cleaning process in a processing chamber includes, without a substrate arranged on a substrate support of the processing chamber, supplying reactant gases in a side gas flow via side tuning holes of a gas distribution device to effect deposition of a coating on an edge ring of the substrate support. The side gas flow targets an outer region of the processing chamber above the edge ring, and the reactant gases are supplied at a first flow rate. The method further includes, while supplying the reactant gases via the side tuning holes, supplying inert gases in a center gas flow via center holes of the gas distribution device. The inert gases are supplied at a second flow rate that is greater than the first flow rate.

### FIELD

The present disclosure relates to substrate processing systems, and more particularly to servicing components of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to confine plasma to a volume above the substrate, protect the substrate support from erosion caused by the plasma, etc.

### SUMMARY

A method for performing a cleaning process in a substrate processing chamber includes, without a substrate arranged on a substrate support of the substrate processing chamber, supplying one or more reactant gases in a side gas flow via side tuning holes of a gas distribution device to effect deposition of a coating on an edge ring of the substrate support. The side gas flow targets an outer region of the substrate processing chamber above the edge ring, and the one or more reactant gases are supplied at a first flow rate. The method further includes, while supplying the one or more reactant gases via the side tuning holes, supplying one or more inert gases in a center gas flow via center holes of the gas distribution device. The center gas flow corresponds to a center region of the substrate support and the one or more inert gases are supplied at a second flow rate that is greater than the first flow rate. The one or more inert gases act to minimize deposition of the coating on the center region of the substrate support.

In other features, a pressure of the substrate processing chamber is adjusted to a desired pressure between 50 and 1000 mTorr. A pressure of the substrate processing chamber is adjusted to a desired pressure between 100 mTorr and 500 mTorr. The first flow rate is 50 to 500 standard cubic centimeters per minute (sccm) and the second flow rate is 500 to 5000 sccm. The first flow rate is 100 to 200 standard cubic centimeters per minute (sccm) and the second flow rate is 1000 to 3000 sccm. A ratio of the second flow rate to the first flow rate is at least 10:1. The one or more reactant gases include at least one of silicon tetrachloride (SiCl₄), silicon tetrafluoride (SiF₄), molecular oxygen (O₂), carbonyl sulfide (COS), and molecular nitrogen (N₂). The one or more inert gases include at least one of argon (Ar), helium (He), neon (Ne), krypton (Kr), and xenon (Xe).

In other features, the supplying of the one or more reactant gases and the supplying of the one or more inert gases are performed during a Waferless Auto Clean (WAC) process. The method further includes, prior to supplying the one or more reactant gases and the one or more inert gases, raising the edge ring. The method further includes providing power to the edge ring to generate plasma in the outer region above the edge ring. The reactant gases include two or more precursors.

A system for performing a cleaning process in a substrate processing chamber includes a controller configured to adjust a pressure of the substrate processing chamber to a desired pressure and a gas delivery system responsive to the controller. The gas delivery system is configured to, without a substrate arranged on a substrate support of the substrate processing chamber, supply one or more reactant gases in a side gas flow via side tuning holes of a gas distribution device to deposit a coating on an edge ring of the substrate support. The side gas flow targets an outer region of the substrate processing chamber above the edge ring and the one or more reactant gases are supplied at a first flow rate. The gas delivery system is further configured to, while supplying the one or more reactant gases via the side tuning holes, supply one or more inert gases in a center gas flow via center holes of the gas distribution device. The center gas flow corresponds to a center region of the substrate support and the one or more inert gases are supplied at a second flow rate that is greater than the first flow rate. The one or more inert gases act to minimize deposition of the coating on the center region of the substrate support.

In other features, the controller is configured to adjust the pressure to between 50 and 1000 mTorr. The controller is configured to adjust the pressure to between 100 mTorr and 500 mTorr. The controller is configured to set the first flow rate to 50 to 500 standard cubic centimeters per minute (sccm) and the second flow rate to 500 to 5000 sccm. The controller is configured to set the first flow rate to 100 to 200 standard cubic centimeters per minute (sccm) and the second flow rate to 1000 to 3000 sccm. A ratio of the second flow rate to the first flow rate is at least 10:1. The one or more reactant gases include at least one of silicon tetrachloride (SiCl₄), silicon tetrafluoride (SiF₄), molecular oxygen (O₂), carbonyl sulfide (COS), and molecular nitrogen (N₂) and the one or more inert gases include at least one of argon (Ar), helium (He), neon (Ne), krypton (Kr), and xenon (Xe).

In other features, the controller is further configured to, prior to supplying the one or more reactant gases and the one or more inert gases, raise the edge ring. The controller is further configured to provide power to the edge ring to generate plasma in the outer region above the edge ring.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example processing chamber according to the present disclosure;

FIG. 2 is an example substrate processing chamber according to the present disclosure;

FIG. 3A illustrates example gas flows directed at a substrate support according to the present disclosure;

FIG. 3B illustrates deposition rates for various gas flows according to the present disclosure;

FIG. 4A shows an example moveable edge ring in a lowered position according to the present disclosure;

FIG. 4B shows an example moveable edge ring in a raised position according to the present disclosure; and

FIG. 5 shows an example method for performing edge ring focused deposition during a cleaning process according to the present disclosure.

In the drawings, reference numbers may be reused to identify similar and/or identical elements.

### DETAILED DESCRIPTION

A substrate support in a substrate processing system may include an edge ring. An upper surface of the edge ring may extend above an upper surface of the substrate support, causing the upper surface of the substrate support (and, in some examples, an upper surface of a substrate arranged on the substrate support) to be recessed relative to the edge ring. This recess may be referred to as a pocket. A distance between the upper surface of the edge ring and the upper surface of the substrate may be referred to as a “pocket depth.” Generally, the pocket depth is fixed according to a height of the edge ring relative to the upper surface of the substrate.

Some aspects of etch processing may vary due to characteristics of the substrate processing system, the substrate, gas mixtures, etc. For example, flow patterns, and therefore an etch rate and etch uniformity, may vary according to the pocket depth of the edge ring, edge ring geometry (i.e., shape), as well as other variables including, but not limited to, gas flow rates, gas species, injection angle, injection position, etc. Non-uniformities in components and process variables can cause non-uniformities in the completed substrate, including, but not limited to, critical dimension (CD) non-uniformity and tilting.

Further, edge rings and other components may comprise consumable materials that wear/erode over time, increasing non-uniformities. Some substrate processing systems may implement moveable (e.g., tunable) edge rings and/or replaceable edge rings. In one example, a height of a moveable edge may be adjusted during processing to control etch uniformity. The height of the edge ring may be adjusted to compensate for erosion. In other examples, edge rings may be removable and replaceable (e.g., to replace eroded or damaged edge rings, to replace an edge ring with an edge ring having different geometry, etc.). Nonetheless, wet clean processes and other maintenance to prevent and/or compensate for edge ring erosion may disproportionately limit a Mean Time Between Cleans (MTBC) of a processing chamber.

A cleaning process such as Waferless Auto Clean (WAC) may include a deposition step to coat components of the processing chamber. In one example, the components are coated in a film that is deposited using reactant gases that are introduced into the processing chamber during the deposition step. The reactant gases may include one or more of, but are not limited to, silicon tetrachloride (SiCl₄), silicon tetrafluoride (SiF₄), molecular oxygen (O₂), carbonyl sulfide (COS), molecular nitrogen (N₂), etc. Coating the components of the processing chamber in this manner may reduce and/or compensate for erosion.

Substrate processing systems and methods according to the principles of the present disclosure implement edge ring focused deposition to extend the MTBC of a processing chamber. For example, a deposition rate of the coating may be tuned to increase deposition on the edge ring while minimizing deposition on other components of the processing chamber (e.g., on an upper surface of the substrate support). In one example, reactant gases are provided via side tuning gas injectors or nozzles while inert gases are provided via center gas injectors or nozzles. For example, the reactant gases may correspond to precursors that are mixed together (e.g., as in chemical vapor deposition) or supplied sequentially (e.g., as in atomic layer deposition). Respective flow rates of the reactant gases and the inert gases and a pressure within the processing chamber may also be adjusted to further tune deposition of the coating. Increased deposition of the coating on the edge ring compensates for and reduces erosion of the edge ring during each etch cycle, minimizing plasma sheath drift and CD non-uniformities and extending MTBC and edge ring life.

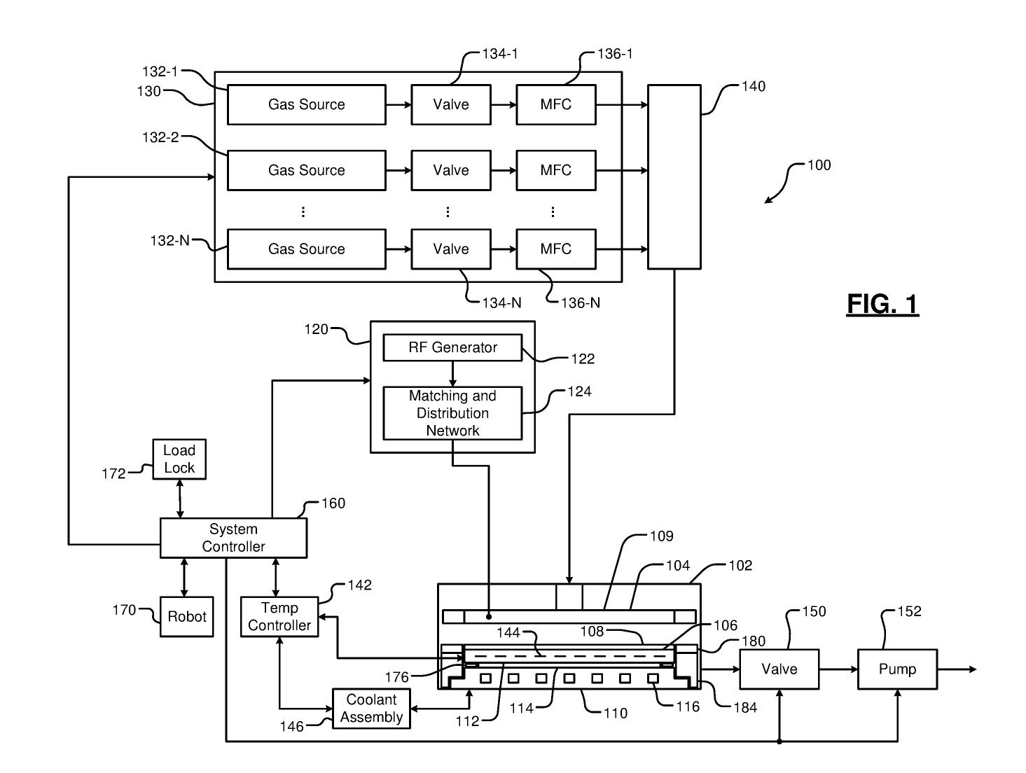

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The processing chamber 102 includes an upper electrode 104 and a substrate support 106, including an electrostatic chuck (ESC). During operation, a substrate 108 is arranged on the substrate support 106. While a specific substrate processing system 100 and processing chamber 102 are shown as an example, the principles of the present disclosure may be applied to other types of substrate processing systems and chambers, such as a substrate processing system that generates plasma in-situ, that implements remote plasma generation and delivery (e.g., using a plasma tube, a microwave tube), etc.

For example only, the upper electrode 104 may include a gas distribution device such as a showerhead 109 that introduces and distributes process gases (e.g., etch process gases). The showerhead 109 may include a stem portion including one end connected to a top surface of the processing chamber 102. A base portion is generally cylindrical and extends radially outwardly from an opposite end of the stem portion at a location that is spaced from the top surface of the processing chamber 102. A substrate-facing surface or faceplate of the base portion of the showerhead 109 includes a plurality of holes through which process gas or purge gas flows. The faceplate may include side tuning holes as described below in more detail. Alternately, the upper electrode 104 may include a conducting plate and the process gases may be introduced in another manner.

The substrate support 106 includes a conductive baseplate 110 that acts as a lower electrode. The baseplate 110 supports a ceramic layer 112. In some examples, the ceramic layer 112 may comprise a heating layer, such as a ceramic multi-zone heating plate. A thermal resistance layer 114 (e.g., a bond layer) may be arranged between the ceramic layer 112 and the baseplate 110. The baseplate 110 may include one or more coolant channels 116 for flowing coolant through the baseplate 110. In some examples, a protective seal 176 may be provided around a perimeter of the bond layer 114 between the ceramic layer 112 and the baseplate 110.

An RF generating system 120 generates and outputs an RF voltage to one of the upper electrode 104 and the lower electrode (e.g., the baseplate 110 of the substrate support 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources 132 supply one or more gases (e.g., etch gas, carrier gases, purge gases, etc.) and mixtures thereof. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109.

A temperature controller 142 may be connected to a plurality of heating elements 144, such as thermal control elements (TCEs) arranged in the ceramic layer 112. For example, the heating elements 144 may include, but are not limited to, macro heating elements corresponding to respective zones in a multi-zone heating plate and/or an array of micro heating elements disposed across multiple zones of a multi-zone heating plate. The temperature controller 142 may be used to control the plurality of heating elements 144 to control a temperature of the substrate support 106 and the substrate 108.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

The substrate support 106 includes an edge ring 180. The edge ring 180 may correspond to a top ring, which may be supported by a bottom ring 184. In some examples, the edge ring 180 is moveable (e.g., moveable upward and downward in a vertical direction) relative to the substrate 108. For example, the edge ring 180 may be controlled via an actuator responsive to the system controller 160. In some examples, the edge ring 180 may be adjusted during substrate processing (i.e., the edge ring 180 may be a tunable edge ring). In other examples, the edge ring 180 may be adjustable during a deposition step of a cleaning process. The substrate processing system 100 according to the principles of the present disclosure is configured to implement an edge ring focused deposition step in a cleaning process as described below in more detail.

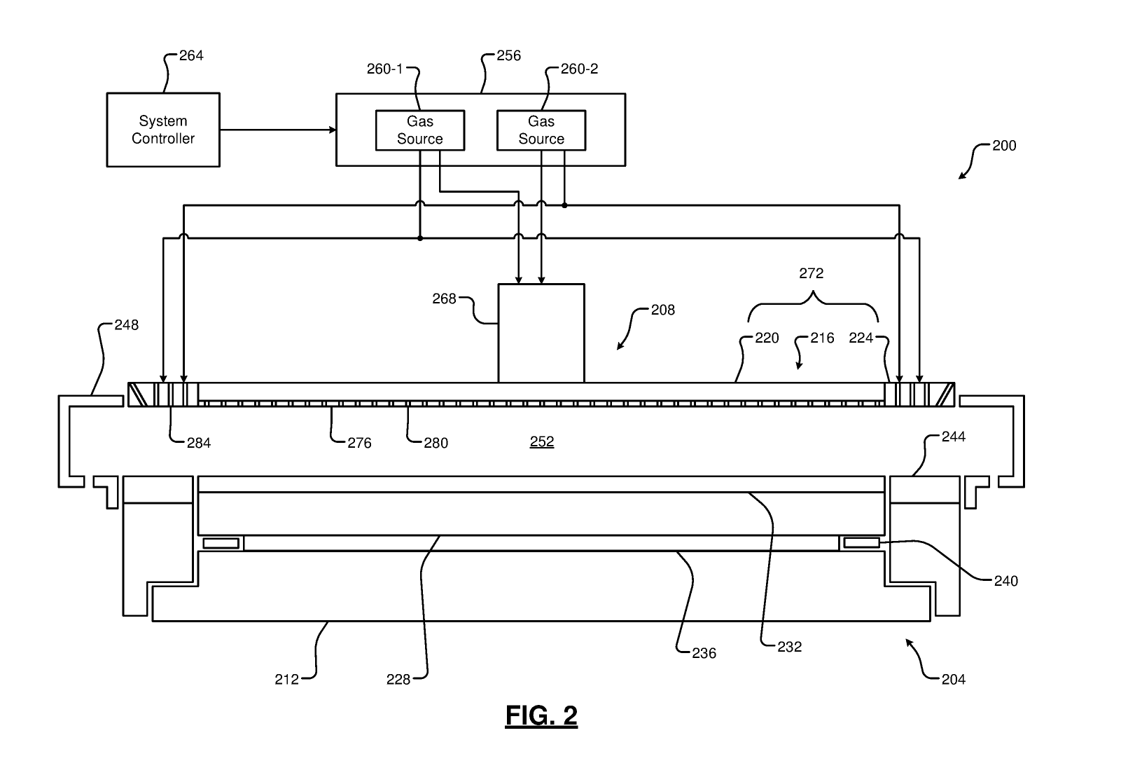

Referring now to FIG. 2, an example substrate processing chamber 200 including a substrate support 204 and a gas distribution device 208 (e.g., a showerhead) is shown in more detail. The substrate support 204 includes a baseplate 212 that may function as a lower electrode. Conversely, the gas distribution device 208 may include an upper electrode 216. In some examples, the upper electrode 216 may include an inner electrode 220 and an outer electrode 224. For example, the inner electrode 220 and the outer electrode 224 may correspond to a disc and annular ring, respectively (i.e., the outer electrode 224 surrounds an outer edge of the inner electrode 220). As used herein for simplicity, the present disclosure will refer to the inner electrode 220 and the outer electrode 224 collectively as the upper electrode 216.

The baseplate 212 supports a ceramic layer 228. The ceramic layer 228 supports a substrate 232. In some examples, a bond layer 236 is arranged between the ceramic layer 228 and the baseplate 212 and a protective seal 240 is provided around a perimeter of the bond layer 236 between the ceramic layer 228 and the baseplate 212. The substrate support 204 may include an edge ring 244 arranged to surround an outer perimeter of the substrate 232. In some examples, the processing chamber 200 may include a plasma confinement shroud 248 arranged around the upper electrode 216. The upper electrode 216, the substrate support 204 (e.g., the ceramic layer 228), the edge ring 244, and the plasma confinement shroud 248 define a processing volume (e.g., a plasma region) 252 above the substrate 232.

A gas delivery system 256 is configured to provide one or more gases and/or a mixture thereof to the substrate processing chamber 200. The gas delivery system 256 is a simplified representation of the gas delivery system 130 as shown in FIG. 1. For example, the gas delivery system 256 may provide gases including, but not limited to, gases from gas sources 260-1 and 260-2, referred to collectively as gas sources 260. As shown, the gas delivery system 256 is configured to provide the gases to the substrate processing chamber 200 in response to commands from a system controller 264, which may correspond to the system controller 160 of FIG. 1.

The gas distribution device 208 may include a stem portion 268 and a base portion 272. For example, the base portion 272 may correspond to the upper electrode 216 including the inner electrode 220, the outer electrode 224, and a faceplate 276. The faceplate 276 includes a plurality of center holes 280. Gases supplied by the gas delivery system 256 flow into the processing volume 252 above the substrate 232 via the center holes 280. For example, the center holes 280 may be arranged to direct gases downward in a central region of the processing volume 252.

Side tuning holes 284 may be provided in the outer electrode 224 for edge tuning as shown. In some examples, the faceplate 276 may at least partially overlap (i.e., extend beneath) the outer electrode 224 and include the side tuning holes 284. For example, the side tuning holes 284 may be arranged to direct gases in an outer (i.e., edge or peripheral) region of the processing volume 252 above the edge ring 244 and/or an outer edge of the substrate 232. The side tuning holes 284 may direct gases downward and/or at an angle.

The system controller 264 according to the principles of the present disclosure is configured to implement edge ring focused deposition during cleaning or other maintenance of the processing chamber 200. For example, the system controller 264 controls the gas delivery system 256 during a coating/deposition step of a WAC process to increase deposition on the edge ring 244 while minimizing deposition on other components of the processing chamber 200 (e.g., on an upper surface of the ceramic layer 228). The substrate 232, although shown in FIG. 2, is typically not present (i.e., not arranged on the ceramic layer 228) during the WAC process.

During the coating (deposition) process, one or more reactant gases and/or mixtures thereof (e.g., precursors) are introduced into the processing chamber 200 to deposit a coating onto surfaces of various components including, but not limited to, the edge ring 244. The reactant gases may include one or more of, but are not limited to, silicon tetrachloride (SiCl₄), silicon tetrafluoride (SiF₄), molecular oxygen (O₂), carbonyl sulfide (COS), molecular nitrogen (N₂), etc. For example, the system controller 264 controls the gas delivery system 256 to supply gases from the gas sources 260 and into the processing chamber 200 through the center holes 280 and/or the side tuning holes 284. The system controller 264 according to the present disclosure is further configured to supply reactant gases (e.g., from the gas source 260-1) to the side tuning holes 284 while supplying inert gases (e.g., from the gas source 260-2) to the center holes 280. The inert gases may include one or more of, but are not limited to, argon (Ar), helium (He), neon (Ne), krypton (Kr), xenon (Xe), etc. Respective flow rates of the reactant gases supplied through the side tuning holes 284 and the inert gases supplied through the center holes 280 may be adjusted to further tune the deposition of the coating on the edge ring 244 as described below in more detail.

For example, the reactant gases are supplied from the side tuning holes 284 at a first flow rate and the inert gases are supplied from the center holes 280 at a second flow rate that is different from (e.g., greater than) the first flow rate. The greater flow rate of the inert gases provided to the central region of the processing volume 252 pushes or otherwise keeps the reactant gases away the central region. In other words, the inert gases restrict the reactant gases from the central region of the processing volume 252 and confine the reactant gases to the outer region of the processing volume 252. In this manner, deposition of the coating during the cleaning process is focused on the edge ring 244.

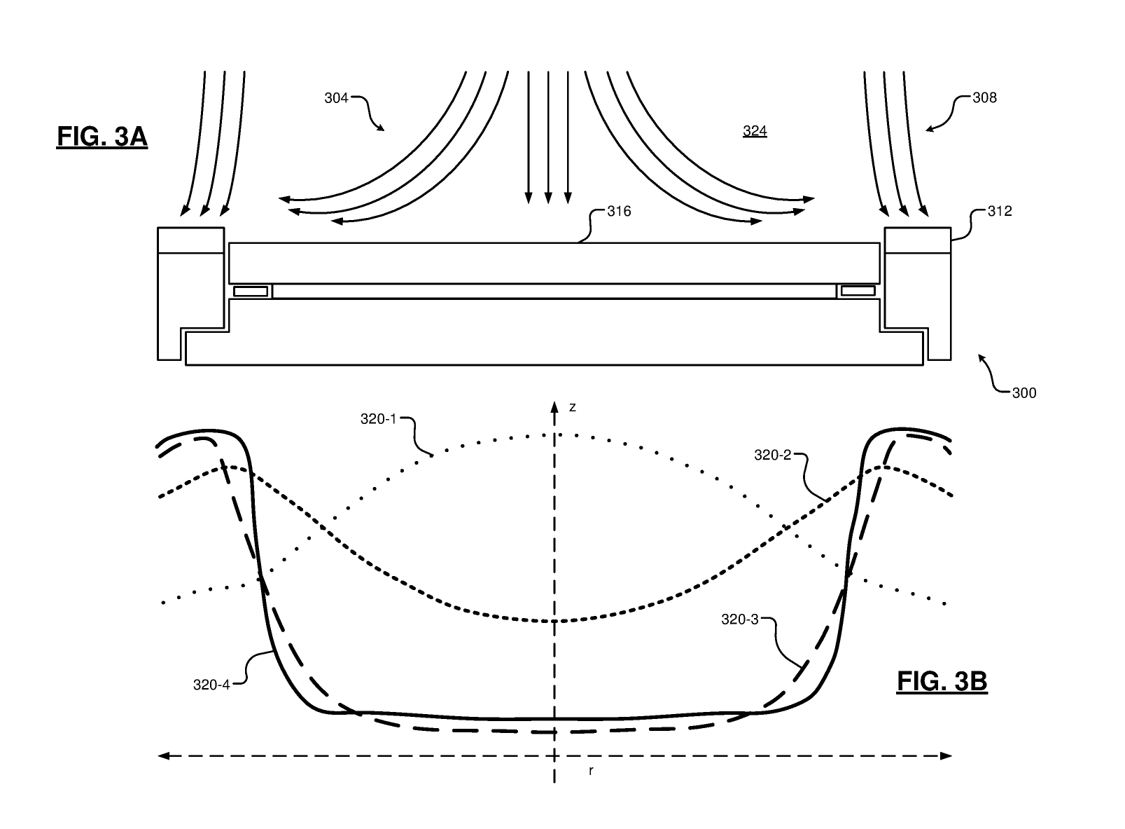

FIG. 3A shows example gas flows directed at a substrate support 300 in a deposition step according to the present disclosure. A center gas flow 304 includes inert gases injected via, for example, the center holes 280. The center gas flow 304 may include one or more of, but are not limited to, argon (Ar), helium (He), neon (Ne), krypton (Kr), xenon (Xe), etc. Conversely, a side or edge gas flow 308 includes deposition (i.e., reactant) gases injected via, for example, the side tuning holes 284. The side gas flow 308 may include one or more of, but are not limited to, silicon tetrachloride (SiCl₄), silicon tetrafluoride (SiF₄), molecular oxygen (O₂), carbonyl sulfide (COS), molecular nitrogen (N₂), etc.

The side gas flow 308 increases reactant density in an outer region above edge ring 312 while the center gas flow 304 pushes or otherwise keeps the reactant gases away from a central region above the substrate support 300 (e.g., above the ceramic layer 316). In this manner, deposition is confined to the edge ring 312. In one example, the side gas flow 308 is supplied at 50 to 500 standard cubic centimeters per minute (sccm) to reduce a mean-free-path to the edge ring 312 and to increase a residence time of the reactant gases above the edge ring 312, further increasing a rate of reaction of the reactant gases in the outer region above the edge ring 312. In another example, the side gas flow 308 is supplied at 100 to 200 sccm. Conversely, the center gas flow 304 may be supplied at a greater flow rate relative to the side gas flow 308 to further prevent reactant gases from diffusing into the center region above the ceramic layer 316. In one example, the center gas flow 304 is supplied at 500 to 5000 sccm. In another example, the center gas flow 304 is supplied at 1000 to 3000 sccm. A ratio of the flow rate of the center gas flow 304 to the flow rate of the side gas flow 308 may be at least 5:1, and in some examples may be 10:1 or 15:1. Accordingly, the deposition step focuses deposition on the edge ring 312 and limits deposition on the ceramic layer 316.

FIG. 3B shows example deposition profiles (referred to collectively as the deposition profiles 320) for various gas flows in a deposition step according to the present disclosure. The deposition profiles 320 illustrate a deposition thickness in a z (i.e. vertical) direction versus a radial distance r from a center of the substrate support 300 for deposition profiles 320-1, 320-2, 320-3, and 320-4. The deposition profile 320-1 illustrates results of a deposition step performed with reactant gases supplied only via the center gas flow 304 (i.e., without any side gas flow 308). In this example, deposition in the center region (i.e., at a smaller radial distance) is greater than deposition in the outer region (i.e., at a greater radial distance corresponding to the edge ring 312).

The deposition profile 320-2 illustrates results of a deposition step performed with reactant gases supplied only via the side gas flow 308 and inert gas supplied via the center gas flow 304. In this example, a flow rate of the inert gas via the center gas flow 304 may be characterized as “low” (e.g., less than 500 sccm). Deposition in the center region is decreased relative to the deposition profile 320-1 while deposition in the outer region is increased relative to the deposition profile 320-1. In other words, the deposition shifts from center-rich to edge-rich. However, deposition in the center region is still substantial.

The deposition profile 320-3 illustrates results of a deposition step performed with reactant gases supplied via the side gas flow 308 and inert gases supplied via the center gas flow 304 at a relatively greater flow rate than in the deposition profile 320-2. For example, the inert gases may be supplied via the center gas flow 304 at greater than 500 sccm (e.g., 1000 to 3000 sccm). In this example, deposition in the center region is further decreased while deposition in the outer region is further increased.

The deposition profile 320-4 illustrates results of a deposition step performed with reactant gases supplied via the side gas flow 308, inert gases supplied via the center gas flow 304 at a relatively high flow rate (e.g., 1000 to 3000 sccm), and an increased pressure within processing chamber 324 (e.g., increased relative to the other examples shown in the deposition profiles 320-1, 320-2, and 320-3. For example, the pressure within the processing chamber 324 may be set to between 50 and 1000 mTorr (e.g., between 100 and 500 mTorr). In this example, the increased pressure decreases a mean free path in the outer region and deposition is maximized in the outer region while narrowing the deposition profile 320-4 in the outer region.

In some examples, the edge ring 312 may be a powered edge ring configured to receive RF power (e.g., at 27 MHz, 60 MHz, or greater). For example, power may be provided to the edge ring 312 to generate plasma in the outer region above the edge ring 312 and further increase deposition rates on the edge ring 312.

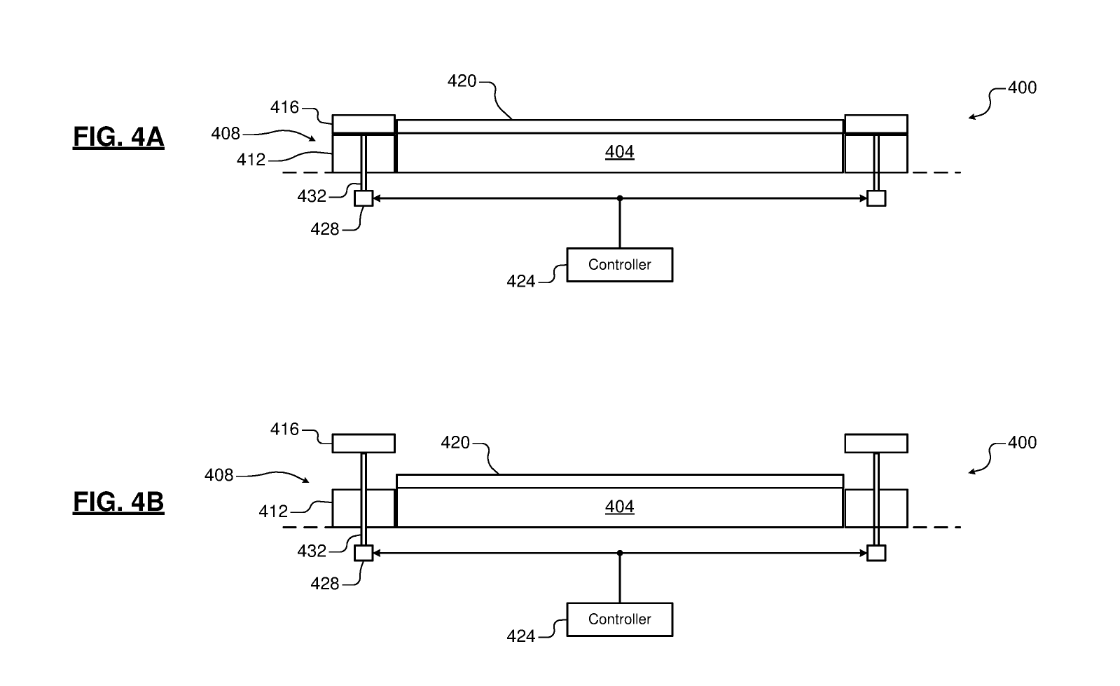

In other examples, the deposition described in FIGS. 3A and 3B may be implemented in processing chambers including a moveable edge ring. For example, referring now to FIGS. 4A and 4B, an example substrate support 400 is shown. The substrate support 400 may include a base or pedestal having an inner portion (e.g., corresponding to an ESC) 404 and an outer portion 408. In examples, the outer portion 408 may be independent from, and moveable in relation to, the inner portion 404. For example, the outer portion 408 may include a bottom ring 412 and a top edge ring 416. A substrate (not shown) may be arranged on the inner portion 404 (e.g., on a ceramic layer 420) for processing. A controller 424 (e.g., corresponding to the system controller 264 of FIG. 2) communicates with one or more actuators 428 to selectively raise and lower the edge ring 416. For example, the edge ring 416 may be raised and/or lowered to adjust a pocket depth of the substrate support 400 during processing. In another example, the edge ring 416 may be raised to facilitate removal and replacement of the edge ring 416. For example only, the edge ring 416 is shown in a fully lowered position in FIG. 4A and in a raised position in FIG. 4B. As shown, the actuators 428 correspond to pin actuators configured to selectively extend and retract pins 432 in a vertical direction. Other suitable types of actuators may be used in other examples.

The controller 424 according to the present disclosure is further configured to raise the edge ring 416 in a deposition step of a cleaning process (e.g., a WAC process) as described above. For example, the edge ring 416 may be raised (e.g., to a maximum height, which may correspond to a height of the edge ring 416 in FIG. 4B) prior to the deposition step. Raising the edge ring 416 in this manner maximizes exposure of surfaces of the edge ring 416 to the reactant gases of the side gas flow 308. Further, the raised position of the edge ring 416 may function as a physical barrier between the reactant gases and outer edges of the ceramic layer 420 to further minimize deposition on the ceramic layer 420. The edge ring 416 is returned to the lowered position (e.g., as shown in FIG. 4A) upon completion of the deposition step.

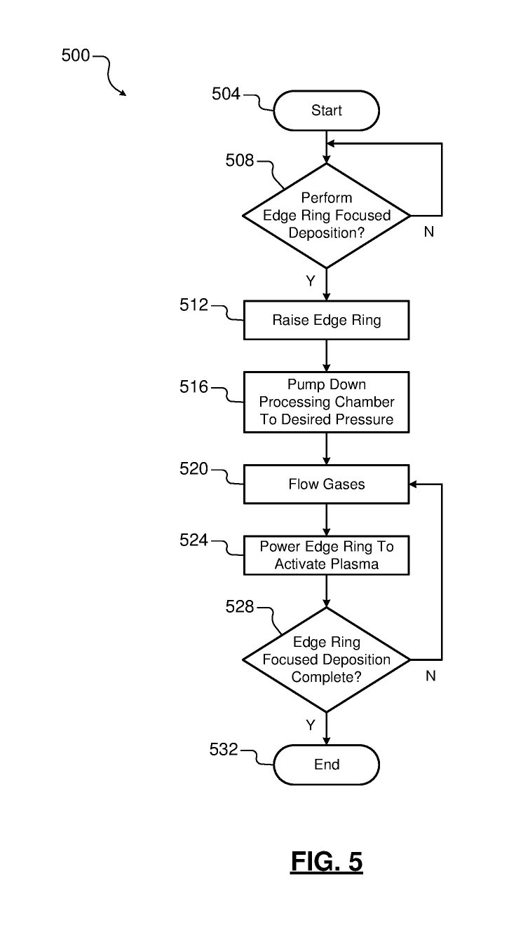

FIG. 5 shows an example method 500 for performing edge ring focused deposition during a cleaning process according to the present disclosure. For example, the method 500 is performed without a substrate arranged on a substrate support in a processing chamber. The method 500 begins at 504. At 508, the method 500 (e.g., the system controller 264) determines whether to perform an edge ring focused deposition process. For example, the system controller 264 may be configured to perform the edge ring focused deposition process each time a cleaning process (e.g., a WAC process) is performed, each time a substrate is removed from the processing chamber subsequent to processing, subsequent to a predetermined number of etch cycles being performed, in response to a command from a user, etc. If true, the method 500 continues to 512. If false, the method 500 continues to 508.

At 512, the method 500 (e.g., the system controller 264) optionally raises an edge ring. For example, in processing chambers including a moveable edge ring as described in FIGS. 4A and 4B, the edge ring is raised to a maximum height prior to deposition. At 516, the method (e.g., the system controller 264) pumps the processing chamber to a desired pressure for edge ring focused deposition (e.g., 100 to 500 mTorr). At 520, the method 500 (e.g., the system controller 264) controls the flow of gases to deposit a coating on the edge ring. For example, reactant gases including two or more precursors are supplied in the side gas flow 308 and inert gases are supplied in the center gas flow 304 as described in FIGS. 3A and 3B. At 524, the method 500 (e.g., the system controller 264) optionally provides power to the edge ring to activate plasma in an outer region above the edge ring.

At 528, the method 500 (e.g., the system controller 264) determines whether the edge ring focused deposition of the cleaning process is complete. For example, the method 500 may perform the deposition for a predetermined period (e.g., 30-60 seconds). If true, the method 500 continues to 532. If false, the method 500 continues to 520. At 532, the method 500 returns the edge ring to a desired position. For example, the edge ring may be lowered to an original positon of the edge ring prior to being raised at 512, moved to a desired position for subsequent processing of a substrate, etc. Further, flows of the reactant and inert gases are stopped and power supplied to the edge ring is stopped. The method 500 ends at 536.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for performing a cleaning process in a substrate processing chamber, the method comprising:
without a substrate arranged on a substrate support of the substrate processing chamber, supplying one or more reactant gases in a side gas flow via side tuning holes of a gas distribution device to effect deposition of a coating on an edge ring of the substrate support, wherein the side gas flow targets an outer region of the substrate processing chamber above the edge ring, and wherein the one or more reactant gases are supplied at a first flow rate; and
while supplying the one or more reactant gases via the side tuning holes, supplying one or more inert gases in a center gas flow via center holes of the gas distribution device , wherein the center gas flow targets a center region of the substrate support, wherein the one or more inert gases are supplied at a second flow rate that is greater than the first flow rate, and wherein the one or more inert gases act to minimize deposition of the coating on the center region of the substrate support.

2. The method of claim 1, further comprising adjusting a pressure of the substrate processing chamber to a desired pressure, wherein the desired pressure is between 50 and 1000 mTorr.

3. The method of claim 1, further comprising adjusting a pressure of the substrate processing chamber to a desired pressure, wherein the desired pressure is between 100 mTorr and 500 mTorr.

4. The method of claim 1, wherein the first flow rate is 50 to 500 standard cubic centimeters per minute (sccm) and the second flow rate is 500 to 5000 sccm.

5. The method of claim 1, wherein the first flow rate is 100 to 200 standard cubic centimeters per minute (sccm) and the second flow rate is 1000 to 3000 sccm.

6. The method of claim 1, wherein a ratio of the second flow rate to the first flow rate is at least 10:1.

7. The method of claim 1, wherein the one or more reactant gases include at least one of silicon tetrachloride (SiCl₄), silicon tetrafluoride (SiF₄), molecular oxygen (O₂), carbonyl sulfide (COS), and molecular nitrogen (N₂).

8. The method of claim 1, wherein the one or more inert gases include at least one of argon (Ar), helium (He), neon (Ne), krypton (Kr), and xenon (Xe).

9. The method of claim 1, wherein the supplying of the one or more reactant gases and the supplying of the one or more inert gases are performed during a Waferless Auto Clean (WAC) process.

10. The method of claim 1, further comprising, prior to supplying the one or more reactant gases and the one or more inert gases, raising the edge ring.

11. The method of claim 1, further comprising providing power to the edge ring to generate plasma in the outer region above the edge ring.

12. The method of claim 1, wherein the one or more reactant gases include two or more precursors.

13. A system for performing a cleaning process in a substrate processing chamber, the system comprising:
a controller configured to adjust a pressure of the substrate processing chamber to a desired pressure; and
a gas delivery system configured to, responsive to the controller,
without a substrate arranged on a substrate support of the substrate processing chamber, supply one or more reactant gases in a side gas flow via side tuning holes of a gas distribution device to deposit a coating on an edge ring of the substrate support, wherein the side gas flow targets an outer region of the substrate processing chamber above the edge ring, and wherein the one or more reactant gases are supplied at a first flow rate; and
while supplying the one or more reactant gases via the side tuning holes, supply one or more inert gases in a center gas flow via center holes of the gas distribution device, wherein the center gas flow targets a center region of the substrate support, wherein the one or more inert gases are supplied at a second flow rate greater than the first flow rate, and wherein the one or more inert gases act to minimize deposition of the coating on the center region of the substrate support.

14. The system of claim 13, wherein the controller is configured to adjust the pressure to between 50 and 1000 mTorr.

15. The system of claim 13, wherein the controller is configured to adjust the pressure to between 100 mTorr and 500 mTorr.

16. The system of claim 13, wherein the controller is configured to set the first flow rate to 50 to 500 standard cubic centimeters per minute (sccm) and the second flow rate to 500 to 5000 sccm.

17. The system of claim 13, wherein the controller is configured to set the first flow rate to 100 to 200 standard cubic centimeters per minute (sccm) and the second flow rate to 1000 to 3000 sccm.

18. The system of claim 13, wherein a ratio of the second flow rate to the first flow rate is at least 10:1.

19. The system of claim 13, wherein the one or more reactant gases include at least one of silicon tetrachloride (SiCl₄), silicon tetrafluoride (SiF₄), molecular oxygen (O₂), carbonyl sulfide (COS), and molecular nitrogen (N₂) and the one or more inert gases include at least one of argon (Ar), helium (He), neon (Ne), krypton (Kr), and xenon (Xe).

20. The system of claim 13, wherein the controller is further configured to at least one of:
prior to supplying the one or more reactant gases and the one or more inert gases, raise the edge ring; and
provide power to the edge ring to generate plasma in the outer region above the edge ring.
